(19) United States
(12) Patent Application Publication
(10) Pub. No.: US 2016/0202315 A1
(43) Pub. Date: Jul. 14, 2016

(54) SYSTEM ON CHIP CAPABLE OF BEING DEBUGGED IN ABNORMAL OPERATING STATE AND DEBUGGING METHOD FOR SYSTEM ON CHIP

(71) Applicant: ALi Corporation, Hsinchu (TW)

(72) Inventors: De-Cai Hu, Guangdong (CN); Rui Yang, Guangdong (CN)

(21) Appl. No.: 14/656,324

(22) Filed: Mar. 12, 2015

(30) Foreign Application Priority Data
Jan. 14, 2015 (CN) 201510018017.4

(51) Int. Cl. G01R 31/3177

(52) U.S. Cl. CPC G01R 31/3177

(57) ABSTRACT

A system on chip capable of being debugged in an abnormal operation state and a debugging method for system on chip are provided. A switch unit is connected to a function module through a first path and is connected to a test connection interface of a processor through a second path. A pin unit is connected to the switch unit through a third path. A control module receives input data, outputs a selection signal to the switch unit, and determines the level of the selection signal according to the input data. The switch unit selects to connect the third path to one of the first path and the second path according to the level of the selection signal. When the third path is connected to the second path, the debugging platform performs a debugging procedure on the processor via the test connection interface.

### CROSS-REFERENCE TO RELATED APPLICATION

This application claims the priority benefit of Chinese application serial no. 201510018017.4, filed on Jan. 14, 2015. The entirety of the above-mentioned patent application is hereby incorporated by reference herein and made a part of this specification.

### BACKGROUND

1. Field of the Invention

The invention is related to a technique of debugging a system on chip, and more particularly to a system on chip capable of being debugged in an abnormal operating state and a debugging method for the system on chip.

2. Description of Related Art

Due to prosperous development of electronic products, there is an increasing demand for a system on chip in the electronic products that can serve more functions with faster processing speed. Consequently, in the process of developing and manufacturing the system on chip, engineers have to spend more with more efforts performing error detection and debugging operation on the designed and manufactured system on chip. Conventionally, engineers use a probe to measure the signal of a pin of the system on chip to inspect whether the system on chip operates well. However, as the pin of the system on chip increases, it is relatively difficult to perform error detection through such approach.

Therefore, a measuring circuit that is established in the system on chip has been developed. Meanwhile, a few testing pins and a serial transmission method are adopted to replace the probe detection. Such construction has currently been set as an industrial standard and called “Joint Test Action Group (JTAG).” At present, most of system on chips provide JTAG boundary scan test structure for testing, developing, and emulation. Initially, the boundary scan test technique was developed in 1988 by a Joint Test Action Group (JTAG) established by some semiconductor corporations (e.g., Philips, IBM, INTEL etc.). In 1990, the JTAG was set as a standard (IEEE1149.1/2/3) for design for testability of electronic products by IEEE. EJTAG (Enhanced Joint Test Action Group) is an expanded version of the basic structure and functions set forth by IEEE 1149.1 established by MIPS Technology Inc., which also performs debugging procedure on system on chip via the JTAG interface.

Based on the above, since a JTAG interface of a processor has to be taken into consideration additionally when the system on chip is designed, extra pins of the system on chip are also required. To reduce the area required for chip and the pins of chip, the JTAG interface of the processor in the system on chip is usually designed to share the pin of system on chip with other function modules in the system on chip, for example, via the control signal inherently generated by the processor to select to connect the debugging interface or other function modules to an external chip pin. However, if the system on chip shows abnormality during the burning process, the functions corresponding to the chip pins cannot be switched through the internal control of the system on chip. Therefore, under the circumstances where the system pin of the system on chip is not connected to the JTAG interface of the processor and the internal operation of the system on chip is in an abnormal state, the debugging procedure cannot be performed on the processor of the system on chip.

### SUMMARY OF THE INVENTION

In light of the above, the invention provides a system on chip capable of being debugged in an abnormal operating state and a debugging method for the system on chip, which may increase and improve testability and ease of maintenance of the system on chip without adding more pins to the system on chip.

The invention provides a system on chip capable of being debugged in a crash state. The chip includes a function module, a processor, a switch unit, a pin unit and a control module. The processor includes a test connection interface. The switch unit is connected to the function module via a first path and connects the processor to the test connection interface via a second path. The pin unit is connected to the switch unit via the third path. The control module is connected to the switch unit, receives input data and outputs a selection signal to the switch unit, and determines a level of the selection signal according to the input data. The switch unit selects to connect the third path to one of the first path and the second path according to the selection signal. When the third path is connected to the second path, a debugging platform performs a debugging procedure on the processor via the test connection interface.

In an embodiment of the invention, the switch unit connects the first path and the third path between the function module and the pin unit in response to the selection signal as a first level. The switch unit connects the second path and the third path between the processor and the pin unit in response to the selection signal as a second level.

In an embodiment of the invention, the control module includes a data detecting module and a data determining module. The data detecting module detects an external signal to receive input data. The data determining module connects the data detecting module to the switch unit and receives the input data. When the data determining module determines that the input data meets a predetermined condition, the data determining module switches the selection signal from the first level to the second level.

In an embodiment of the invention, when the data determining module determines that the input data does not meet the predetermined condition, the data determining module does not change the level of the selection signal so that the level of the selection signal remains to be the first level or the second level.

In an embodiment of the invention, when the input data is consistent with a predetermined condition sequence, the data determining module determines that the input data meets the predetermined condition. When the input data is inconsistent with the predetermined condition sequence, the data determining module determines that the input data does not meet the predetermined condition.

In an embodiment of the invention, when the switch unit connects the second path and the third path between the processor and the pin unit and the processor is connected to a debugger via the pin unit, the debugging platform uses the debugger to perform a debugging procedure on the processor via the test connection interface. Meanwhile, the debugger is connected between the processor and the debugging platform.

In an embodiment of the invention, the first path includes a plurality of first interface transmission path that supports the interface transmission standard of the test connection interface. The second path includes a plurality of second interface transmission path that supports the data transmission standard of the function module.

In an embodiment of the invention, the processor is in an abnormal operation state or crash state.

From another perspective, the invention provides a debugging method for a system on chip. The system on chip includes a processor, a function module and a pin unit. The method includes the following steps. A switch unit is provided, wherein the processor is connected to a switch unit via a first path, the function module is connected to the switch unit via a second path, and the switch unit is connected to the pin unit via a third path. Input data is received to determine a level of a selection signal. The switch unit selects to connect the third path to one of the first path and the second path according to the selection signal. When the third path is connected to the second path, a debugging platforms performs a debugging procedure on the processor via the test connection interface of the processor.

Based on the above, with the switch unit and external input data, the invention may switch the pin of the system on chip to connect to the test connection interface of the processor. Accordingly, even if the system on chip is in an abnormal operation state or crash state, the system on chip is able to switching the pin of the system on chip to connect to the test connection interface of the processor according to the control operation of designers so that the debugging platform can perform the debugging procedure on the processor via the test connection interface of the processor. This way, the invention may make it more convenient to perform debugging procedure on the system on chip and avoid the situation that the debugging procedure is prevented due to abnormality of the system on chip, such that the chip can be developed with faster speed and higher efficiency.

In order to make the aforementioned features and advantages of the disclosure more comprehensible, embodiments accompanying figures are described in detail below.

### BRIEF DESCRIPTION OF THE DRAWINGS

FIG. 1 is a schematic view illustrating a chip debugging system according to an embodiment of the invention.

FIG. 2 is a schematic view illustrating a chip debugging system according to an embodiment of the invention.

FIG. 3 is a schematic view illustrating a switch unit according to an embodiment of the invention.

FIG. 4 is a flowchart of a debugging method for a system on chip according to an embodiment of the invention.

### DESCRIPTION OF EMBODIMENTS

Generally speaking, under the circumstances where a debugging interface of a processor shares pins of a system on chip with a function module, the pins of the system on chip is usually set to be connected to the function module. The invention may switch the function definition corresponding to the pins of the system on chip via an external input data to avoid the situation that the debugging procedure is prevented to be performed on the processor via the chip pin when the processor is in an abnormal operation state. In order to make the features of the disclosure more comprehensible, embodiments are described in detail below as examples that show the invention can actually be implemented.

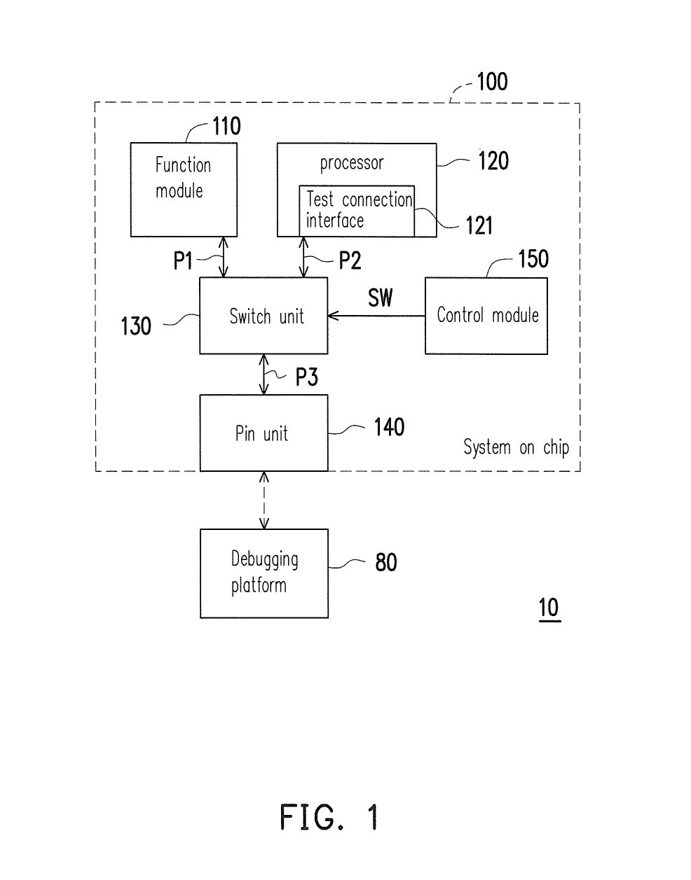

FIG. 1 is a schematic view illustrating a chip debugging system according to an embodiment of the invention. Please refer to FIG. 1. A chip debugging system 10 includes a system on chip 100 and a debugging platform 80. The debugging platform 80 is, for example, a desktop computer, a notebook computer or other computing devices that serve computing functions; the invention provides no limitation to the above. The system on chip 100 is formed by constructing various kinds modules having different functions on a single chip. For example, the system on chip 100 may include a processor, a digital signal processor or a memory and so on, which should not be construed as a limitation to the invention.

In an embodiment, the system on chip 100 includes a function module 110, a processor 120, a switch unit 130, a pin unit 140 and a control module 150. The function module 110 is a circuit module having a specific function, or may be a memory or a digital signal processor. For instance, the function module 110 is, for example, a smart card module for communicating with a smart card and performs a corresponding operation using the data in the smart card. In addition, the function module 110 may also be an image processing module; however, the invention provides no limitation to the actual function of the function module 110. In other words, the system on chip 100 may be constructed as a multi-functional single chip through integrating various kinds of function modules.

The processor 120 is a core unit in the system on chip 100. The processor 120 may control the overall operation of the system on chip 100. The processor 120 may be a single-core processor or may be a heterogeneous multi-core processor or a homogeneous multi-core processor among the multi-core processors. The core structure of the processor 120 is, for example, ARM developed by ARM, System/370 developed by IBM, X86 and X86-64 developed by Intel, MIPS developed by MIPS and so on, which should not be construed as a limitation to the invention.

The debugging platform 80 may debug the processor 120 via operation of debugging software to test whether the software or hardware of the processor 120 meets the designer's expectation. Alternatively, the debugging platform 80 may debug the system on chip 100 via operation of the debugging software to eliminate the error occurred in the processor 120. For example, an integrated development environment (IDE) platform is an integrated debugging system software for performing debugging procedure on the end of the debugging platform 80, which may provide a user operation interface to be operated by the designer to give instructions.

In an embodiment, the processor 120 includes a test connection interface 120. The test connection interface 121 may include the hardware element (e.g., a specific circuit or storage unit etc.) required by the debugging processor 120 and/or a software element (e.g., a software module or function etc. that are used specifically for realizing a specific function). The processor 120 may be connected to the debugging platform 80 via the test connection interface 121 to receive the debugging instruction given by the debugging platform 80 and returns the debugging result to the debugging platform 80. The test connection interface 121 is, for example, a signal transmission interface that supports the JTAG protocol (IEEE1149.1); however, the invention provides no limitation to the type of the test connection interface 121. For example, the test connection interface 121 may also be a signal transmission interface that supports high-speed digital circuit boundary scan test protocol (IEEE1149.6).

The pin unit 140 of the system on chip 100 includes a plurality of pins so that the system on chip 100 can be configured on the circuit board and connected to other elements on the circuit board for communication. Specifically, the pin unit 140 may allow the circuit module in the packaged system on chip 100 to be connected to an external element for transmitting a signal to the external element or receiving the signal emitted by the external element. In the embodiment, the invention provides no limitation to the total amount of the pin in the pin unit 140. However, the pin unit 140 at least includes a plurality of pins that support the signal transmission protocol of the test connection interface 121.

The switch unit 130 is connected to the function module 110 via a first path P1. The switch unit 130 is connected to the test connection interface 121 of the processor 120 via the second path P2. The pin unit 140 is connected to the switch unit 130 via the third path P3. The switch unit 130 may be a switch, a multiplexer, a logic circuit or an element formed by a combination of the above, which should not be construed as a limitation to the invention. The switch unit 130 may select to connect the third path P3 to the first path P1, or select to connect the third path P3 to the second path P2. The first path P1 may include a plurality of first interface transmission path that supports the interface transmission standard of the test connection interface 121. The second path P2 may include a plurality of second interface transmission path that supports the data transmission standard of the function module 110.

When the third path P3 is connected to the first path P1, the pin unit 140 is connected to the function module 110. Accordingly, the system on chip 100 may transmit the signal generated by the function module 110 out of the system on chip 100 via the pin unit 140, or transmit an external signal to the function module 110 via the pin unit 140. On the other hand, when the third path P3 is connected to the second path P2, the pin unit 140 is connected to the test connection interface 121 of the processor 120. Accordingly, the system on chip 100 may transmit the signal that supports the signal transmission protocol corresponding to the test connection interface 121 via the pin unit 140, and transmit the debugging result of the processor 120 out of the system on chip 100 via the pin unit 140.

The control module 150 is connected to the switch unit 130, receives input data and outputs a selection signal SW to the switch unit 130, and determines a level of the selection signal SW according to the input data. The control module 150 may autonomously receive the input data; however, the invention provides no limitation to the data format and transmission method of the input data. The control module 150 may receive the input data via physical connection or wireless remote control. The switch unit 130 selects to connect the third path P3 to one of the first path P1 and the second path P2 according to the selection signal SW. That is to say, the switch unit 130 may select to connect the function module 110 or the test connection interface 121 to the pin unit 140 according to the input data. Accordingly, when the third path P3 is connected to the second path P2, the debugging platform 80 may perform the debugging procedure on the processor 120 via the test connection interface 121.

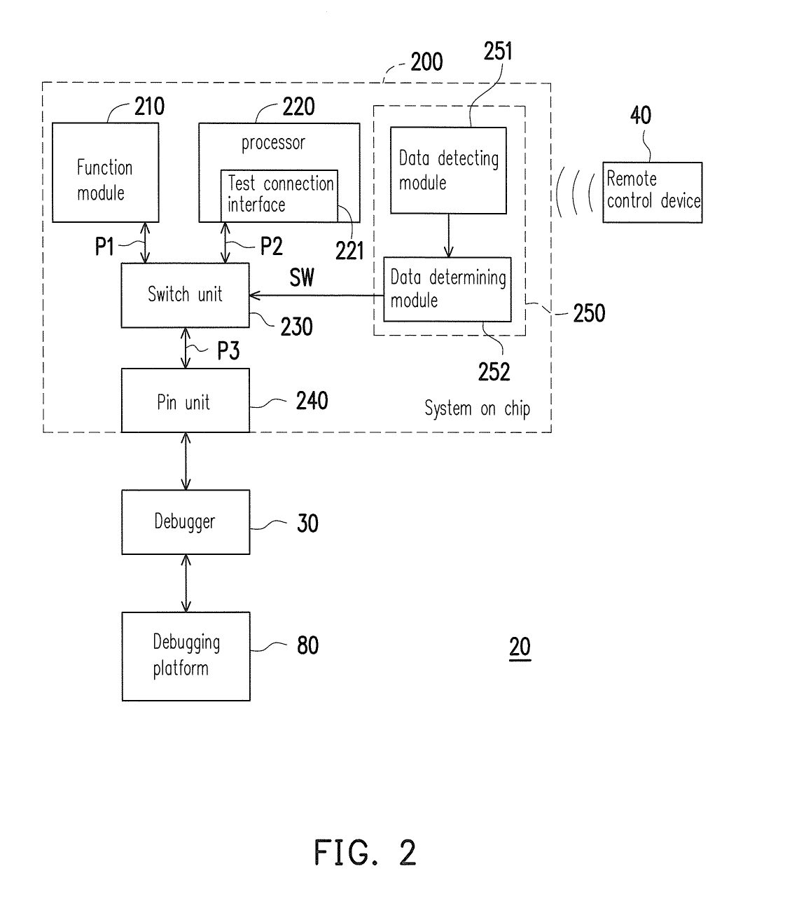

FIG. 2 is a schematic view illustrating a chip debugging system according to an embodiment of the invention. Please refer to FIG. 2. A chip debugging system 20 includes a system on chip 200, a debugger 30, a remote control device 40 and a debugging platform 80. The system on chip 200 includes a function module 210, a processor 220, a switch unit 230, a pin unit 240 and a control module 250. The function module 210 is connected to the switch unit 230 via a first path P1. The test connection interface 221 of the processor 220 is connected to the switch unit 230 via the second path P2. In addition, the pin unit 240 is connected to the switch unit 230 via the third path P3. The control module 250 outputs a selection signal SW to the switch unit 230 to control the switch state of the switch unit 230.

However, the connection relation and functions of the function module 210, the processor 220, the switch unit 230 and the pin unit 240 are identical or similar to the connection relation and functions of the function module 110, the processor 120, the switch unit 130 and the pin unit 140 as illustrated by FIG. 1; therefore, no further descriptions are incorporated herein. The difference between the present embodiment and the previous embodiment lies in that the control module 250 includes a data detecting module 251 and a data determining module 252. The data detecting module 251 is coupled to the data determining module 252 to detect an external signal generated by the remote control device 40 so as to receive the external input data. The data determining module 252 transmits the input data to the data determining module 252, and the data determining module 252 receives the input data to deter line whether the input data meets a predetermined condition.

In an embodiment of the invention, the data detecting module 251 is, for example, an infrared ray monitor (IR Monitor) that may be used to receive the infrared signal emitted by the remote control device 40 and obtain a corresponding input data according to the infrared signal. In other words, the remote control device 40 is an electronic device that may emit the infrared signal according to the designer's control. However, although the above example is described by using the IR Monitor and the remote control device as an example, the invention is not limited thereto. The data detecting module 251 may also be a data transmission interface that supports an inter-integrated circuit (12C) or universal asynchronous receiver-transmitter (UART) protocol to receive the external input data.

The switch unit 230 may determine the switch state in response to the level of the selection signal SW. In an embodiment of the invention, the switch unit 230 connects the second path P2 and the third path P3 between the processor 220 and the pin unit 240 in response to the selection signal SW as the second level. The switch unit 230 connects the first path P1 and the third path P3 between the function module 210 and the pin unit 240 in response to the selection signal SW as the first level. Here, the first level may be a high level, and the second level may be a low level, which should not be construed as a limitation to the invention. In another embodiment, the first level may be a low level and the second level may be a high level.

In an embodiment of the invention, when the data determining module 252 determines that the input data meets the predetermined condition, the data determining module 252 switches the selection signal SW from the first level to the second level. On the other hand, when the data determining module 252 determines that the input data does not meet the predetermined condition, the data determining module 252 does not change the level of the selection signal SW, so that the level of the selection signal SW remains to be the first level or the second level. In other words, when the input data does not meet the predetermined condition, the switch unit 230 does not change the current switch state.

Moreover, in an embodiment of the invention, the data determining module 252 may include a memory to store a predetermined condition sequence, and include a shift register to store the input data transmitted by the data detecting unit 251. The sequence in the shift register may shift according to the input data that is input in. Therefore, when the input data is consistent with the predetermined condition sequence, the data determining module 252 determines that the input data received by the data detecting module 251 meets the predetermined condition. On the other hand, when the input data is inconsistent with the predetermined condition sequence, the data determining module 252 determines that the input data received by the data detecting module 251 does not meet the predetermined condition. In brief, the data determining module 252 determines whether the input data meets the predetermined condition by comparing the consistency between the predetermined condition sequence and the input data, so as to further determine whether to change the selection signal SW or not; however, the invention is not limited thereto. In other embodiments, the data determining module 252, for example, may determine whether the sum or other statistical characteristic of the input data meets the predetermined condition so as to decide whether to change the level of the selection signal SW.

Furthermore, when the switch unit 230 connects the second path P2 and the third path P3 between the processor 220 and the pin unit 240, and provided that the test connection interface 221 is connected to the debugger 30 (e.g., in-circuit emulator (ICE)) via the pin unit 240, the debugging platform 80 uses the debugger 30 to perform the debugging procedure on the processor 220 via the test connection interface 221. The debugger 30 is connected between the processor 220 and the debugging platform 80. The debugger 30 converts the signal from the debugging platform 80 to the signal supporting a protocol practically used by the test connection interface 221. For example, the debugger 30, for instance, is connected to the debugging platform 80 via the universal serial bus (USB) protocol interface or a network interface (e.g., TCP/IP protocol interface). In the meantime, the debugger 30 is, for example, connected to the test connection interface 221 via the JTAG protocol interface. That is to say, in the case where the third path P3 is connected to the first path P1 instead of the second path P2, even if the processor 220 is in an abnormal operation state or crash state, the system on chip 200 may still perform the debugging procedure via the switch operation performed by the control module 252.

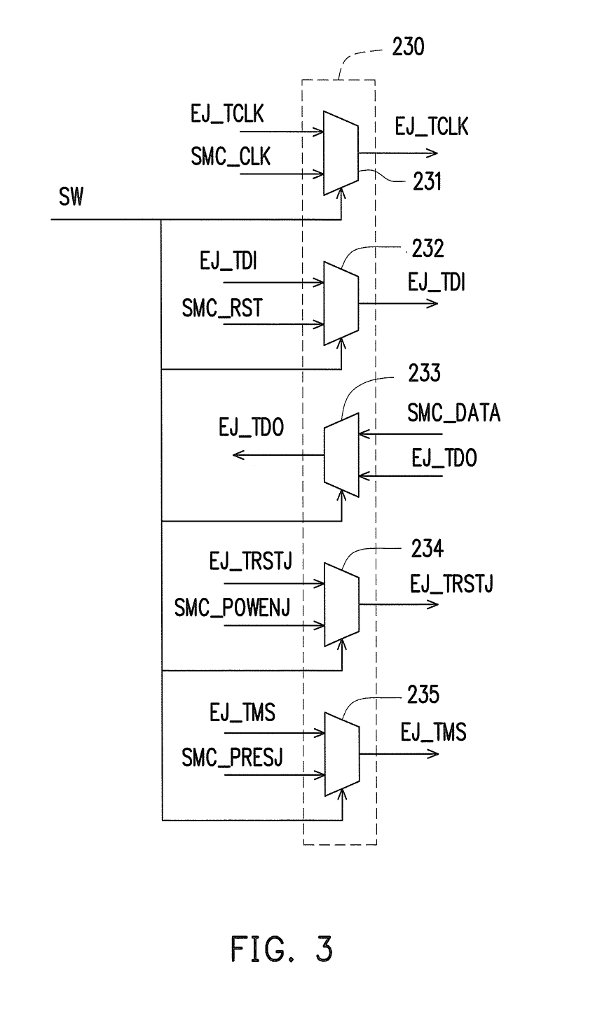

To describe the invention in details, FIG. 3 is a schematic view illustrating a switch unit according to an embodiment of the invention. It should be specifically indicated that, here, suppose the test connection interface 221 of the processor supports the EJTAG protocol, and therefore the second path between the test connection interface 221 and the pin unit 240 includes five signal transmission lines. The signal transmission lines of the second path are respectively configured to transmit a test clock signal EJ_TCLK, a test data registration signal EJ_TDI, a test data output signal EJ_TDO, a test reset signal EJ_TRSTJ and a test mode selection signal EJ_TMS.

In addition, in the embodiment, assuming the function module 210 is a smart card module; likewise, the first path between the function module 210 and the pin unit 240 also includes five signal transmission lines. The signal transmission lines of the first path are respectively configured to transmit a card clock signal SMC_CLK, a reset signal SMC_RST, a card data signal SMC_DATA, a power signal SMC_POWENJ and a predetermined signal SMC_PRESJ.

Please refer to FIG. 3. The switch unit 230 includes multiplexers 231-235. The control terminals of the multiplexers 231-235 respectively receive the selection signal SW emitted by the control module 250 so as to output one of the signals received by two input terminals according to the level of the selection signal SW. The first input terminal of the multiplexer 231 receives the test clock signal EJ_TCLK, and the second input terminal of the multiplexer 231 receives the card clock signal SMC_CLK. The first input terminal of the multiplexer 232 receives the test data registration signal EJ_TDI, and the second input terminal of the multiplexer 232 receives the reset signal SMC_RST. The first input terminal of the multiplexer 233 receives the test data output signal EJ_TDO, and the second input terminal of the multiplexer 233 receives the card data signal SMC_DATA. The first input terminal of the multiplexer 234 receives the test reset signal EJ_TRSTJ, and the second input tell signal of the multiplexer 234 receives the power signal SMC_POWENJ. The first input terminal of the multiplexer 235 receives the test mode selection signal EJ_TMS, and the second input terminal of the multiplexer 235 receives the predetermined signal SMC_PRESJ.

As shown by FIG. 3, the switch unit 230 may connect the connection path between the processor 220 and the pin unit 240 in response to the level of the selection signal SW to output the test clock signal EJ_TCLK, test information registration signal EJ_TDI, test reset signal EJ_TRSTJ and the test mode selection signal EJ_TMS out of the system on chip 200 via the pin unit 240, and to receive the test information output signal EJ_TDO out of the system on chip 200 via the pin unit 240. Accordingly, even if the system on chip 200 is in an abnormal operation state or crash state, the debugging platform 80 may still perform the debugging procedure on the processor 220 via the debugger 30.

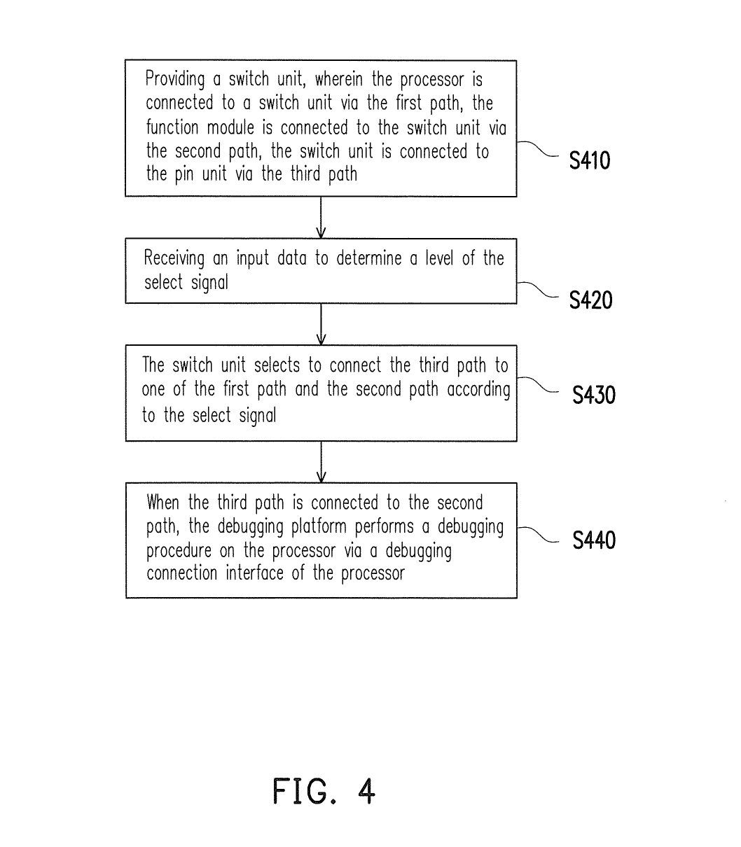

FIG. 4 is a flowchart of a debugging method for a system on chip according to an embodiment of the invention. In the embodiment, the debugging method for the system on chip is suitable for the system on chips 100 and 200 shown by FIG. 1 or 2; however, the invention is not limited thereto.

First of all, in step S410, a switch unit is provided, wherein the processor is connected to the switch unit via the first path; the function module is connected to the switch unit via the second path; and the switch unit is connected to the pin unit via the third path. In step S420, the input data is received to determine the level of the selection signal. In step S430, the switch unit selects to connect the third path to one of the first path and the second path according to the selection signal. In step S440, when the third path is connected to the second path, the debugging platform perform is the debugging procedure on the processor via the test connection interface of the processor. Each of the steps shown by FIG. 4 may be comprehensible for persons skilled in the art based on the descriptions concerning FIGS. 1-3; therefore, no further descriptions are incorporated herein.

To sum up, in the embodiments of the invention, the control module of the system on chip may control the switch unit autonomously according to the external input data, such that the switch unit may select to connect the pins of the system on chip to the function module or the test connection interface of the processor according to the input data. In that case, even if the system on chip is in an abnormal operation state or crash state, the test connection interface of the processor may still be connected to the pin of the system on chip through the designer's control, so that the debugging platform may perform the debugging procedure on the processor in the crash state via the test connection interface of the processor. Based on the above, the invention may allow the chip debugging system to be used more conveniently and avoid the situation that the debugging procedure is prevented due to abnormality of the system on chip. In addition, the invention may perform error detection in real time when abnormality occurs in the processor, whereby significantly improving the speed and efficiency of chip development.

Although the invention has been disclosed by the above embodiments, the embodiments are not intended to limit the invention. It will be apparent to those skilled in the art that various modifications and variations can be made to the structure of the invention without departing from the scope or spirit of the invention. Therefore, the protecting range of the invention falls in the appended claims.

What is claimed is:

1. A system on chip capable of being debugged under an abnormal state, the chip comprising:
a function module;
a processor comprising a test connection interface;
a switch unit connected to the function module via a first path, and connected to the test connection interface of the processor via a second path;
a pin unit connected to the switch unit via a third path;
a control module connected to the switch unit, receiving input data and outputting a selection signal to the switch unit, and determining a level of the selection signal according to the input data, wherein the switch unit selects to connect the third path to one of the first path and the second path according to the selection signal,
wherein, when the third path is connected to the second path, a debugging platform perform is a debugging procedure on the processor via the test connection interface.

2. The system on chip according to claim 1, wherein the switch unit connects the first path and the third path between the function module and the pin unit in response to the selection signal as a first level, and the switch unit connects the second path and the third path between the processor and the pin unit in response to the selection signal as a second level.

3. The system on chip according to claim 1, wherein the control module comprises:
a data detecting module detecting an external signal to receive the input data; and
a data determining module connected to the data detecting module and the switch unit and receiving the input data, wherein the data determining module switches the selection signal from the first level to the second level when the data determining module determines that the input data meets a predetermined condition.

4. The system on chip according to claim 3, wherein the data determining module does not change the level of the selection signal when the data determining module determines that the input data does not meet the predetermined condition, such that the level of the selection signal remains to be the first level or the second level.

5. The system on chip according to claim 3, wherein the data determining module determines that the input data meets the predetermined condition when the input data is consistent with a predetermined condition sequence; and the data determining module determines that the input data does not meet the predetermined condition when the input data is inconsistent with the predetermined condition sequence.

6. The system on chip according to claim 1, wherein, when the switch unit connects the second path and the third path between the processor and the pin unit and the processor is connected to a debugger via the pin unit, the debugging platform uses the debugger to perform the debugging procedure on the processor via the test connection interface, wherein the debugger is connected between the processor and the debugging platform.

7. The system on chip according to claim 1, wherein the first path comprises a plurality of first interface transmission path supporting an interface transmission standard of the test connection interface, the second path comprises a plurality of second interface transmission path supporting a data transmission standard of the function module.

8. A debugging method for a system on chip, wherein the system on chip comprises a processor, a function module and a pin unit, the method comprising:
providing a switch unit, wherein the processor is connected to the switch unit via the first path, the function module is connected to the switch unit via the second path, and the switch unit is connected to the pin unit via the third path;
receiving input data to determine a level of a selection signal;
selecting to connect the third path to one of the first path and the second path according to the selection signal by the switch unit; and
performing a debugging procedure on the processor by a debugging platform via a test connection interface of the processor when the third path is connected to the second path.

9. The debugging method according to claim 8, wherein the step of selecting to connect the third path to one of the first path and the second path according to the selection signal by the switch unit comprises:
connecting the first path and the third path between the function module and the pin unit by the switch unit in response to the selection signal as a first level; and
connecting the second path and the third path between the processor and the pin unit by the switch unit in response to the selection signal as a second level.

10. The debugging method according to claim 8, wherein the step of receiving the input data to determine the level of the selection signal comprises:
detecting an external signal to receive the input data; and
switching the selection signal from the first level to the second level when the input data meets a predetermined condition.

11. The debugging method according to claim 10, further comprising:
keeping the level of the selection signal unchanged when the input data does not meet the predetermined condition, such that the level of the selection signal remains to be the first level or the second level.

12. The debugging method according to claim 10, further comprising:
determining whether the input data is consistent with a predetermined condition sequence;
determining that the input data meets the predetermined condition when the input data is consistent with the predetermined condition sequence; and
determining that the input data does not meet the predetermined condition when the input data is inconsistent with the predetermined condition sequence.

13. The debugging method according to claim 10, wherein the step of performing the debugging procedure on the processor by the debugging platform via the test connection interface of the processor comprises:
using the debugger to perform the debugging procedure on the processor via the test connection interface when the processor is connected to a debugger via the pin unit, wherein the debugger is connected between the processor and the debugging platform.

14. The debugging method according to claim 8, wherein the first path comprises a plurality of first interface transmission path supporting an interface transmission standard of the test connection interface, and the second path comprises a plurality of second interface transmission path supporting a data transmission standard of the function module.
